(19) United States
(12) Patent Application Publication
(10) Pub. No.: US 2023/0071917 A1
(43) Pub. Date: Mar. 9, 2023

(54) ENCAPSULATED ORGANIC LIGHT EMITTING DEVICE AND METHOD FOR FABRICATION THEREOF

(71) Applicant: ELECTRONICS AND TELECOMMUNICATIONS RESEARCH INSTITUTE, Daejeon (KR)

(72) Inventors: Gi Heon KIM, Daejeon (KR); Yong Hae KIM, Daejeon (KR); Won Jae LEE, Daejeon (KR)

(21) Appl. No.: 17/669,674

(22) Filed: Feb. 11, 2022

(30) Foreign Application Priority Data
Sep. 3, 2021 (KR) 10-2021-0117570

(51) Int. Cl. H01L 51/52; H01L 27/32; H01L 51/56

(52) U.S. Cl. CPC H01L 51/5259; H01L 27/3246; H01L 51/56; H01L 51/5253; H01L 2227/323

(57) ABSTRACT

An encapsulated organic light emitting device and a fabrication method thereof are disclosed. An encapsulated organic light emitting device according to an example embodiment includes a plurality of organic light emitting devices formed on a substrate, a partition wall disposed to separate the plurality of organic light emitting devices, a hydrophobic oil filling a housing structure defined by the partition wall, a polymer thin film formed on surfaces of the hydrophobic oil and the partition wall using a photo-curable precursor, and a multi-film laminated on the polymer thin film.

### CROSS-REFERENCE TO RELATED APPLICATION

This application claims the benefit of Korean Patent Application No. 10-2021-0117570 filed on Sep. 3, 2021, in the Korean Intellectual Property Office, the entire disclosure of which is incorporated herein by reference for all purposes.

### BACKGROUND

### 1. Field of the Invention

One or more example embodiments relate to an encapsulated organic light emitting device and a method for fabrication thereof.

### 2. Description of Related Art

An organic light emitting device is formed on an anode formed on a flexible or rigid substrate, and includes a hole transport layer that injects holes into an organic light emitting layer, the organic light emitting layer formed on the hole transport layer, an electron injection layer formed on the organic light emitting layer to inject electrons into the organic light emitting layer, and a cathode connected to the electron injection layer.

The organic light emitting device has excellent characteristics such as a wide viewing angle, high speed response, high contrast, high luminous efficiency, and no need for a separate light source.

The related art described above is possessed or acquired by the inventor in the process of deriving the disclosure of the present application, and is not necessarily known art published to the general public prior to the present application.

### SUMMARY

The organic light emitting device is very vulnerable to moisture and oxygen, and when electrode materials of the organic light emitting device are oxidized and its characteristics deteriorate, the lifespan of the organic light emitting device is rapidly reduced. Accordingly, in order to secure stability and reliability of the organic light emitting device, it may be required to develop a technology capable of efficiently blocking penetration of moisture and oxygen into the organic light emitting device.

However, the technical tasks are not limited to the above-described technical tasks, and other technical tasks may exist.

According to an aspect, there is provided an encapsulated organic light emitting device including a plurality of organic light emitting devices formed on a substrate, a partition wall disposed to separate the plurality of organic light emitting devices, a hydrophobic oil filling a housing structure defined by the partition wall, a polymer thin film formed on surfaces of the hydrophobic oil and the partition wall using a photo-curable precursor, and a multi-film laminated on the polymer thin film.

The height of the partition wall may be 0.5 µm to 5 µm, and the partition wall may be a trapezoidal pixel defining layer (PDL) with a lower portion wider than an upper portion.

The hydrophobic oil may have a refractive index of 1.29 to 1.6, a contact angle with water of 90 degrees or more, and a specific gravity of 1.2 or more, and may be one of fluorine oil, siloxane oil, paraffin oil, amorphous fluorine-based oil, silicone oil, mineral oil, almond oil, corn oil, cottonseed oil, linseed oil, tung oil, castor oil, cinnamin oil, and coconut oil. The fluorine oil may include an amorphous fluoropolymer, the siloxane oil may include polyphenyl-methyl siloxane, polydiphenyl siloxane, and polydimethyl siloxane, and the amorphous fluorine-based oil may include tetrafluoroethylene, trifluoroethylene, difluoroethylene, 2,2-bisfluoromethyl-4,5-difluoro-1,3-dixole, and chlorotrifluoroethylene.

The polymer thin film may have a thickness of 1 µm or less, and may be formed by coating the photo-curable precursor on the surfaces of the hydrophobic oil and the partition wall followed by a curing reaction or by filling the housing structure with a liquid in which the photo-curable precursor is mixed with the hydrophobic oil followed by a curing reaction of a phase-separated photo-curable precursor.

The photo-curable precursor may be a mixture in which one or more of a reactive precursor, a photoinitiator, and an additive are combined.

The reactive precursor may have a specific gravity of 1.0 to 1.2 and may have less miscibility and specific gravity than the hydrophobic oil, and the reactive precursor may include one or more of 1,6-hexandiol diacrylate (HAD), 2-hydroxyethyl methacrylate (2-HEMA), 2-ethylheeth acrylate, hydroxyethyl acrylate (HEA), methyl methacrylate (MMA), methacrylate (MA), isobornyl acrylate (IOBA), 2-(2-ethoxyethoxy) ethyl acrylate (EOEOEA), triethylopropane triacrylate (TMPTA), trimethylolpropane dially ether (TMPDE), tri(propylene glycol) diacrylate (TPGDA), pentaerythritol triacrylate (PETA), ethylene glycol dimethacrylate (EGDA), triethylopropane trimethacrylate (TMPTMA), 2-phenoxyethyl acrylate (2-PEA), trimethylolpropane ethoxylate triacrylate (TMPEOTA), tetrahydrofurfuryl acrylate (THFA), and urethane diacrylate.

The photoinitiator may have a weight of 0.1% to 10% of the polymer thin film and may be a mixture of two or more UV curing agents.

The curing reaction may use ultraviolet rays having a wavelength in a range of 300 nm to 400 nm, and use photocuring energy of 20 mJ to 2000 mJ.

The multi-film is formed by laminating an encapsulation layer on an adhesive sheet including one of a double-sided adhesive made using a double-sided adhesive film and the double-sided adhesive film, and the encapsulation layer may be one of an encapsulation film which is a film in which plastic and inorganic material are laminated or a multilayer film formed by laminating only the inorganic material, and a glass substrate.

The double-sided adhesive film may be coated with an adhesive layer including only one polymer of acrylate and epoxy-based polymers, and the double-sided adhesive may be formed by repeating a structure in which the adhesive layer, a support for supporting the adhesive layer, and the adhesive layer are laminated.

The encapsulated organic light emitting device may further include a moisture absorption layer for absorbing moisture and oxygen in the atmosphere between the encapsulation layer and the adhesive sheet or a moisture absorbent may be added to the double-sided adhesive.

According to an aspect, there is provided a fabrication method of fabricating an encapsulated organic light emitting device including forming a plurality of organic light emitting devices on a substrate, forming a partition wall disposed to separate the plurality of organic light emitting devices, filling a housing structure defined by the partition wall with a hydrophobic oil, forming a polymer thin film on surfaces of the hydrophobic oil and the partition wall using a photo-curable precursor, and laminating a multi-film on the polymer thin film.

The height of the partition wall may be 0.5 µm to 5 µm, and the partition wall may be a trapezoidal PDL with a lower portion wider than an upper portion.

The hydrophobic oil may have a refractive index of 1.29 to 1.6, a contact angle with water of 90 degrees or more, and a specific gravity of 1.2 or more.

The polymer thin film may have a thickness of 1 µm or less, and may be formed by coating the photo-curable precursor on the surfaces of the hydrophobic oil and the partition wall followed by a curing reaction or by filling the housing structure with a liquid in which the photo-curable precursor is mixed with the hydrophobic oil followed by a curing reaction of a phase-separated photo-curable precursor.

The photo-curable precursor may be a mixture in which one or more of a reactive precursor, a photoinitiator, and an additive are combined, the reactive precursor may have a specific gravity of 1.0 to 1.2 and may have less miscibility and specific gravity than the hydrophobic oil, and the photoinitiator may have a weight of 0.1% to 10% of the polymer thin film and may be a mixture of two or more UV curing agents.

The multi-film may be formed by laminating one of a double-sided adhesive made using a double-sided adhesive film and the double-sided adhesive film and an encapsulation layer, and the encapsulation layer may be one of an encapsulation film and a glass substrate.

The the double-sided adhesive film may be coated with an adhesive layer including only one polymer of acrylate and epoxy-based polymers, and the double-sided adhesive may be formed by repeating a structure in which the adhesive layer, a support for supporting the adhesive layer, and the adhesive layer are laminated.

The encapsulated organic light emitting device may further include a moisture absorption layer for absorbing moisture and oxygen in the atmosphere between the encapsulation layer and the adhesive sheet or a moisture absorbent may be added to the double-sided adhesive.

According to another aspect, there is provided a display including an encapsulated organic light emitting device and a thin film transistor (TFT) inserted between a substrate of the encapsulated organic light emitting device and an organic light emitting device. The encapsulated organic light emitting device may include a plurality of organic light emitting devices formed on the substrate, a partition wall disposed to separate the plurality of organic light emitting devices, a hydrophobic oil filling a housing structure defined by the partition wall, a polymer thin film formed on surfaces of the hydrophobic oil and the partition wall using a photo-curable precursor, and a multi-film laminated on the polymer thin film.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a diagram for explaining a display including an encapsulated organic light emitting device according to various example embodiments;

FIG. 2 is a diagram for explaining an encapsulated organic light emitting device according to various example embodiments;

FIG. 3 is an example of a structural diagram of the organic light emitting device shown in FIG. 2;

FIG. 4A is a flowchart for explaining an example of a process of forming a polymer thin film according to various example embodiments;

FIG. 4B is a flowchart for explaining another example of an operation of forming a polymer thin film according to various example embodiments;

FIG. 5 is a diagram for explaining a multi-film according to various example embodiments; and

FIG. 6 is a flowchart of an example of a method of fabricating an encapsulated organic light emitting device according to various example embodiments.

### DETAILED DESCRIPTION

Specific structural or functional descriptions of example embodiments are disclosed for purposes of illustration only, and may be changed and implemented in various forms. Accordingly, actual implementation is not limited to specific example embodiments disclosed, and the scope of the present specification includes changes, equivalents, or substitutes included in the technical spirit described as example embodiments.

Although terms such as first or second may be used to describe various elements, these terms should be interpreted merely for the purpose of distinguishing one element from another element. For example, a first element may be named a second element, and similarly, a second element may also be named a first element.

When an element is referred to as being “connected to” another element, it may be directly connected or joined to the other element, but it should be understood that another element may exist in between.

A singular expression includes a plural expression unless the context clearly dictates otherwise. In this specification, it should be understood that terms such as “comprise”, “include”, or “have” are intended to indicate that a described feature, number, step, operation, element, part, or combination thereof exists, and does not preclude in advance the possibility of addition or presence of one or more other features, numbers, steps, operations, elements, parts, or combinations thereof.

Unless defined otherwise, all terms used herein, including technical or scientific terms, have the same meanings as commonly understood by a person skilled in the art. Terms such as those defined in commonly used dictionaries should be interpreted as having meanings consistent with meanings in the context of the related art, and should not be interpreted in ideal or excessively formal meanings unless explicitly defined in the present specification.

Hereinafter, example embodiments will be described in detail with reference to the accompanying drawings. In descriptions with reference to the accompanying drawings, the same elements are indicated by the same reference numerals regardless of numerals in the drawings, and overlapping descriptions thereof will be omitted.

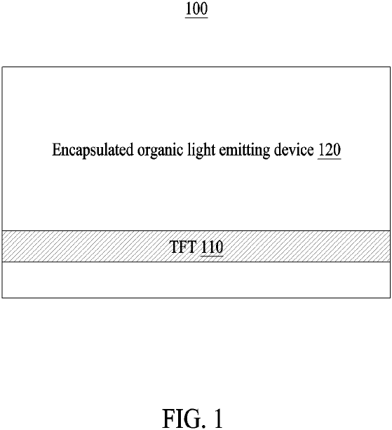

FIG. 1 is a diagram for explaining a display including an encapsulated organic light emitting device according to various example embodiments.

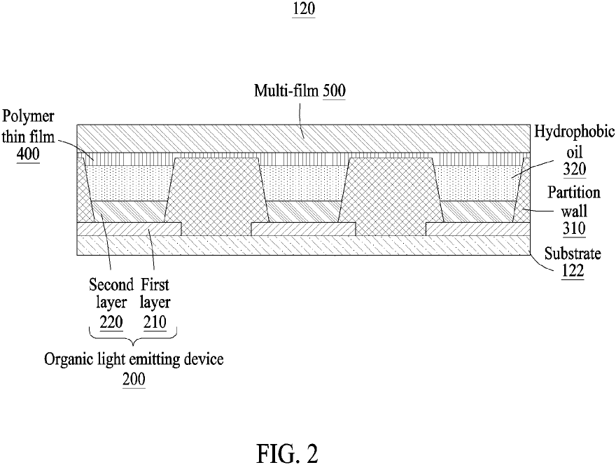

Referring to FIG. 1, according to various example embodiments, a display 100 may include a thin film transistor (TFT) 110 and an encapsulated organic light emitting device 120. The display 100 may be formed by inserting the TFT 110 between a substrate (for example, a substrate 122 of FIG. 2) included in the encapsulated organic light emitting device 120 and an organic light emitting device (for example, an organic light emitting device 200 of FIG. 2). The TFT 110 may transmit an electric signal to the organic light emitting device 200 to control the organic light emitting device 200 in units of pixels. The encapsulated organic light emitting device 120 may protect the organic light emitting device 200 from moisture and oxygen to increase the lifespan of the organic light emitting device 200 and increase reliability and stability as a device.

FIG. 2 is a diagram for explaining an encapsulated organic light emitting device according to various example embodiments.

Referring to FIG. 2, according to various example embodiments, the encapsulated organic light emitting device 120 may include the substrate 122, the organic light emitting device 200, a partition wall 310, a hydrophobic oil 320, a polymer thin film 400, and a multi-film 500. The encapsulated organic light emitting device 120 may protect the organic light emitting device 200 from penetration of moisture and oxygen by the partition wall 310, the hydrophobic oil 320, the polymer thin film 400, and the multi-film 500.

According to various example embodiments, a plurality of organic light emitting devices 200 may be formed on the substrate 122. The substrate 122 may be a flexible substrate made of one of plastic, thin glass, and metal foil. The partition wall 310 may have a PDL structure that divides a pixel boundary of the organic light emitting device 200 or another structure having substantially the same function as the PDL structure to separate each organic light emitting device 200 and may be disposed on the organic light emitting device 200. The partition wall 310 may be formed using a photosensitive high heat-resistant organic material and may have a trapezoidal shape with a lower portion wider than an upper portion, and the height of the partition wall 310 may be 0.5 µm to 5 µm.

According to various example embodiments, a housing structure defined by the partition wall 310 may be filled with the hydrophobic oil 320. The hydrophobic oil 320 may have excellent barrier properties against oxygen and moisture to be suitable for a barrier and heat-sink. The hydrophobic oil 320 may have a refractive index of 1.29 to 1.6, a contact angle with water of 90 degrees or more, and a specific gravity of 1.2 or more. For example, the hydrophobic oil 320 may be one of fluorine oil, siloxane oil, paraffin oil, amorphous fluorine-based oil, silicone oil, mineral oil, almond oil, corn oil, cottonseed oil, linseed oil, tung oil, castor oil, cinnamin oil, and coconut oil. The fluorine oil may include an amorphous fluoropolymer, the siloxane oil may include polyphenyl-methyl siloxane, polydiphenyl siloxane, and polydimethyl siloxane, and the amorphous fluorine-based oil may include tetrafluoroethylene, trifluoroethylene, difluoroethylene, 2,2-bisfluoromethyl-4,5-difluoro-1,3-dixole, and chl orotrifluoroethyl ene.

According to various example embodiments, the polymer thin film 400 may be formed using a photo-curable precursor on surfaces of the hydrophobic oil 320 and the partition wall 310 to fix the hydrophobic oil 320. The thickness of the polymer thin film 400 may be 1 µm or less.

According to various example embodiments, it is possible to prevent contamination from occurring due to movement of the hydrophobic oil 320 during an encapsulation process by the multi-film 500 and improve the reliability of the organic light emitting device 200, by forming the polymer thin film 400 on the surfaces of the hydrophobic oil 320 and the partition wall 310.

According to various example embodiments, the photo-curable precursor may be a mixture in which one or more of a reactive precursor, a photoinitiator, and an additive are combined. The reactive precursor may have a specific gravity of 1.0 to 1.2, and may have less miscibility and specific gravity than the hydrophobic oil 320. For example, the reactive precursors may include one or more of 1,6-hexandiol diacrylate (HAD), 2-hydroxyethyl methacrylate (2-HEMA), 2-ethylheeth acrylate, hydroxyethyl acrylate (HEA), methyl methacrylate (MMA), methacrylate (MA), isobornyl acrylate acrylate (IOBA), 2-(2-ethoxyethoxy) ethyl acrylate (EOEOEA), triethylopropane triacrylate (TMPTA), trimethylolpropane dially ether (TMPDE), tri(propylene glycol) diacrylate (TPGDA), pentaerythritol triacrylate (PETA), ethylene glycol dimethacrylate (EGDA), triethylopropane trimethacrylate (TMPTMA), 2-phenoxyethyl acrylate (2-PEA), trimethylolpropane ethoxylate triacrylate (TMPEOTA), tetrahydrofurfuryl acrylate (THFA), and urethane diacrylate.

According to various example embodiments, the photoinitiator may be 0.1% to 10% by weight of the polymer thin film 400 and may be a mixture of two or more UV curing agents to improve the curing rate during a curing reaction of the photo-curable precursor (for example, a photocuring reaction). For example, the UV curing agent may be one of Benzophenone, 1-Hydroxy-cyclohexyl-phenyl-ketone (Irgacure 907), JR Cure, 2-Methyl-1[4-(methylthio)phenyl]-2-morpholinopropane-1-one (Irgacure 184C), 1-Hydroxy-2-methyl-1-phenyl-propane-1-one (Darocur 1173), an initiator obtained by mixing 50 wt% of Irgacure 184C and 50 wt% of Benzophenone (Irgacure 500), an initiator obtained by mixing 20 wt% of Irgacure 184 and 80 wt% of Irgacure 1173 (Irgacure 1000), 2-Hydroxy-1-[4-(2-hydroxyethoxy)phenyl]-2-methyl-1 propanone (Irgacure 2959), Methylbenzoylformate (Darocur MBF), Alpha, alpha-dimethoxy-alpha-phenylacetophenone (Irgacure 651), 2-Benzyl-2-(dimethylamino)-1-[4-(morpholinyl) phenyl]-1-butanone (Irgacure 369), an initiator obtained by mixing 30 wt% of Irgacure 369 and 70 wt% of Irgacure 651 (Irgacure 1300), Diphenyl (2,4,6-trimethylbenzoyl)-phosphine oxide (Darocur TPO), an initiator obtained by mixing 50 wt% of Darocure TPO and 50 wt% of Darocur 1173 (Darocur 4265), Phosphine oxide, phenyl bis(2,4,6-trimethyl benzoyl) (Irgacure 819), 2-hydroxy-2-methyl-1-phenylpropane-1-one (Darocur 1173), an initiator obtained by mixing 5wt% of Irgacure 819 and 95 wt% of Darocure 1173 (Irgacure 2005), an initiator obtained by mixing 10 wt% of Irgacure 819 and 90 wt% of Darocure 1173 (Irgacure 2010), an initiator obtained by mixing 20 wt% of Irgacure 819 and 80 wt% of Darocure 1173 (Irgacure 2020), Bis(.eta. 5-2,4-cyclopentadien-1-yl) bis[2,6-difluoro-3-(1H-pyrrol-1-yl)phenyl]titanium (Irgacure 784), a mixed initiator containing benzophenone (HSP 188), 1-hydroxy-cyclohexylphenyl-ketone (CPA), and 2,4,6,-trimethylbenzoyl-diphenyl-phosphineoxide (Darocur TPO). The additive may include one or more of a surfactant, an antifoaming agent, and a UV stabilizer.

According to various example embodiments, the multi-film 500 may be laminated on the polymer thin film 400. The multi-film 500 may protect the organic light emitting device 200 from the penetration of moisture and oxygen and damage caused by external shocks or scratches together with the hydrophobic oil 320.

According to various example embodiments, the encapsulated organic light emitting device 120 may include a moisture and oxygen barrier film formed in a desired shape in a short time at low production cost without using expensive equipment (for example, a physical/chemical vacuum chamber, and a vacuum pump) by encapsulation using the above-described hydrophobic oil 320, the polymer thin film 400, and the multi-film 500. Therefore, it is possible to easily manufacture a low-cost, light-weight, large-area device using the encapsulated organic light emitting device 120. Since the hydrophobic oil 320 and the multi-film 500 of the encapsulated organic light emitting device 120 block double moisture and oxygen, it is possible to increase the lifespan of the organic light emitting device 200 and improve the mechanical reliability and stability of the organic light emitting device 200 by effectively preventing the permeation of moisture and oxygen, which cause device degradation. In addition, the encapsulated organic light emitting device 120 may be bendable because it is based on the substrate 122 made from one of plastic, thin glass, and metal foil, plastics, and inorganic materials (for example, SiC, SiN, SiO, A12O3, A1N, SiON).

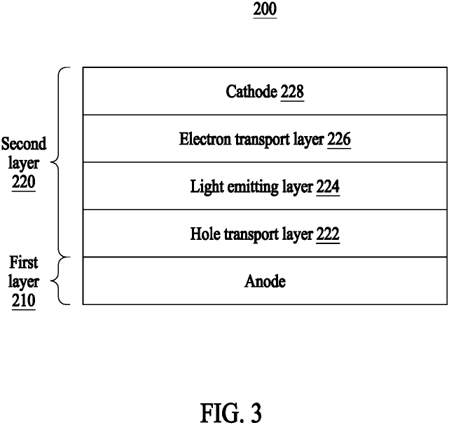

FIG. 3 is an example of a structural diagram of the organic light emitting device shown in FIG. 2.

Referring to FIG. 3, according to various example embodiments, the organic light emitting device 200 may include a first layer 210 and a second layer 220. The first layer 210 may be an anode, and the second layer 220 may include a hole transport layer 222, a light emitting layer 224, an electron transport layer 226, and a cathode 228. The first layer 210 may be formed through a first process of forming a pattern by coating and etching a metal material, and the second layer 220 may be formed through a second process of sequentially depositing the hole transport layer 222, the light emitting layer 224, the electron transport layer 226, and the cathode 228 included in the second layer 220 after removing a residual film and impurities on the first layer 210 using plasma. The organic light emitting device 200 may have a structure in which the hole transport layer 222 for injecting holes into the light emitting layer 224 on the anode 210 formed on a substrate (for example, the substrate 122 of FIG. 2), the light emitting layer 224 formed on the hole transport layer 222, the electron transport layer 226 formed on the light emitting layer 224 to inject electrons, and the cathode 228 formed on the electron transport layer 226 are sequentially laminated. The organic light emitting device 200 may receive the electrons and the holes injected through the anode 210 and the cathode 228, form excitons by recombination of the injected electrons and holes, and generate light of a specific wavelength by energy of the formed exciton in the light emitting layer 224.

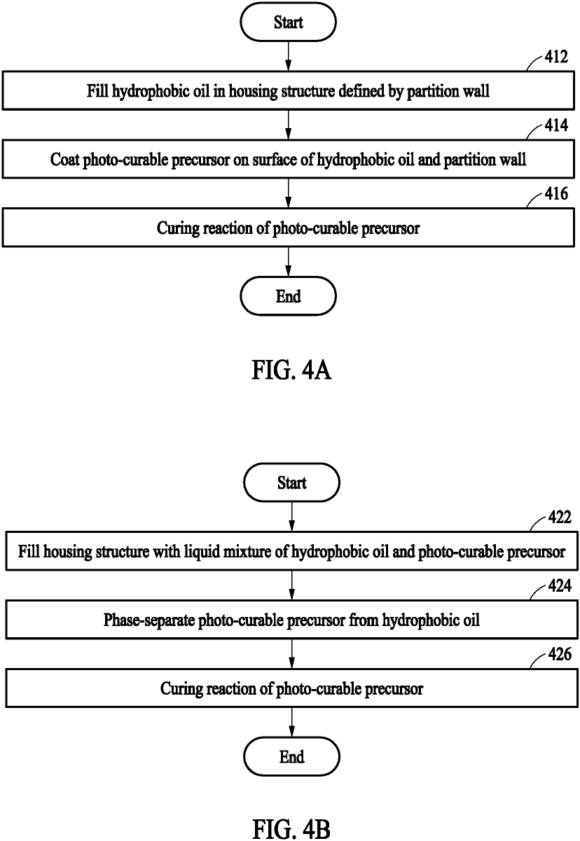

FIG. 4A is a flowchart for explaining an example of a process of forming a polymer thin film according to various example embodiments.

Referring to FIG. 4A, according to various example embodiments, operations 412 to 416 may be for explaining an example of a method of forming a polymer thin film (for example, the polymer thin film 400 of FIG. 2).

In operation 412, a hydrophobic oil (for example, the hydrophobic oil 320 of FIG. 2) may be filled in a housing structure by a partition wall (for example, the partition wall 310 of FIG. 2).

In operation 414, a photo-curable precursor may be coated on surfaces of the hydrophobic oil 320 and the partition wall 310. The photo-curable precursor may be a combination of at least one of a reactive precursor, a photoinitiator, and an additive, and the reactive precursor may have a small miscibility with the hydrophobic oil 320 and a specific gravity of 1.0 to 1.2 which is less than the specific gravity of the hydrophobic oil 320.

In operation 416, the polymer thin film 400 may be formed by injecting light into the photo-curable precursor to induce a curing reaction of the photo-curable precursor. The photo-curable precursor may be cured in response to the light. UV light having a wavelength of 300 nm to 400 nm may be injected into the photo-curable precursor, and photocuring energy of 20 mJ to 2000 MJ may be used for the curing reaction.

FIG. 4B is a flowchart for explaining another example of an operation of forming a polymer thin film according to various example embodiments.

Referring to FIG. 4B, according to various example embodiments, operations 422 to 426 may be for explaining another example of a method of generating a polymer thin film (for example, the polymer thin film 400 of FIG. 2).

In operation 422, the encapsulated organic light emitting device 120 may include a housing structure defined by a partition wall (for example, the partition wall 310 of FIG. 2) filled with a liquid mixture of a hydrophobic oil (for example, the hydrophobic oil 320 of FIG. 2) and a photo-curable precursor. Compared to the case of coating and curing the photo-curable precursor on the surfaces of the hydrophobic oil 320 and the partition wall 310, the encapsulated organic light emitting device 120 may increase process convenience because the housing structure is filled with the liquid mixture so that coating of the photo-curable precursor is omitted.

In operation 424, the encapsulated organic light emitting device 120 may phase-separate the photo-curable precursor from the hydrophobic oil 320. The photo-curable precursor may be phase-separated due to the differences in miscibility and specific gravity from the hydrophobic oil 320 to be positioned on the surface of the hydrophobic oil 320.

In operation 426, the encapsulated organic light emitting device 120 may inject light into the phase-separated photo-curable precursor to induce a curing reaction of the photo-curable precursor to form a polymer thin film. The photo-curable precursor may be cured in response to the light. UV light having a wavelength of 300 nm to 400 nm may be injected into the photo-curable precursor, and photocuring energy of 20 mJ to 2000 mJ may be used for the curing reaction.

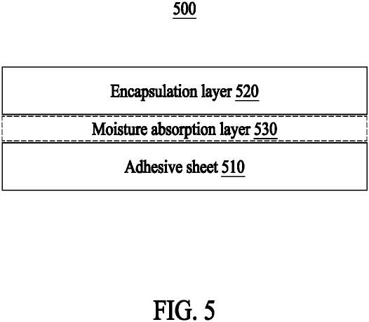

FIG. 5 is a diagram for explaining a multi-film according to various example embodiments.

Referring to FIG. 5, according to various example embodiments, a multi-film 500 may include an adhesive sheet 510 and an encapsulation layer 520. The multi-film 500 may further include a moisture absorption layer 530. The multi-film 500 may be formed by sequentially laminating the adhesive sheet 510 and the encapsulation layer 520 on a polymer thin film to protect the organic light emitting device 200 from moisture, oxygen, and damage from the outside. The adhesive sheet 510 may be one of a double-sided adhesive made using a double-sided adhesive film and the double-sided adhesive film. The double-sided adhesive film may have a structure coated with an adhesive layer made of one or more polymers of acrylate and epoxy-based polymers, and the double-sided adhesive may be formed by repeating a laminated structure of an adhesive layer, a support for supporting the adhesive layer, and an adhesive layer. The encapsulation layer 520 may be an encapsulation film which is a film in which plastic and inorganic material (for example, SiC, SiN, SiO, A12O3, A1N, SiON) are laminated or a multilayer film formed by laminating only inorganic material, or a glass substrate.

According to various example embodiments, in the multi-film 500, the moisture absorption layer 530 may be inserted between the adhesive sheet 510 and the encapsulation layer 520 or a moisture absorbent may be added to the double-sided adhesive to absorb moisture and oxygen in the atmosphere. The moisture absorption layer and the moisture absorbent may include at least one of calcium, silica gel, zeolite, and alkali metal.

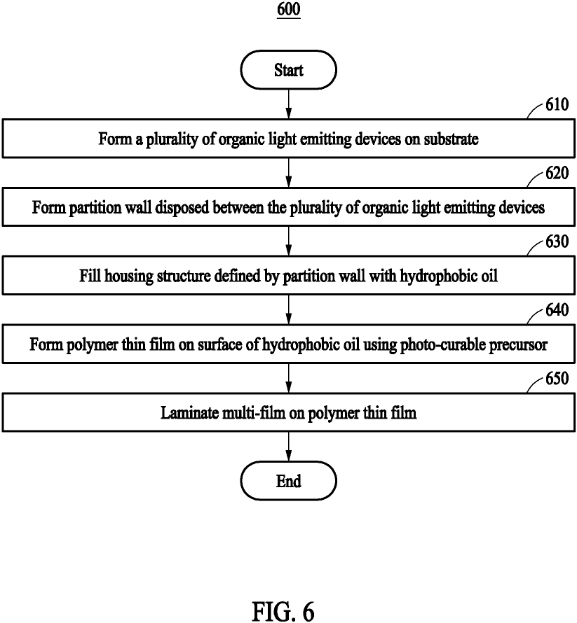

FIG. 6 is a flowchart of an example of a method of fabricating an encapsulated organic light emitting device according to various example embodiments.

Referring to FIG. 6, according to various example embodiments, operations 610 to 650 may be for describing an example of a method of fabricating an encapsulated organic light emitting device (for example, the encapsulated organic light emitting device 120 of FIG. 2).

In operation 610, the encapsulated organic light emitting device 120 may include a plurality of organic light emitting devices (for example, the organic light emitting device 200 of FIG. 2) formed on a substrate (for example, the substrate 122 of FIG. 2). The substrate 122 may be a flexible substrate made from one of plastic, thin glass, and metal foil.

In operation 620, the encapsulated organic light emitting device 120 may include the partition wall 310 disposed between the organic light emitting devices 200 to separate the plurality of organic light emitting devices 200. The partition wall 310 may have the PDL structure that separates the pixel boundary or may have another structure having the same function. The partition wall 310 may be formed using a photosensitive high heat-resistant organic material and may have a trapezoidal shape with a lower portion wider than an upper portion, and the height of the partition wall 310 may be 0.5 µm to 5 µm.

In operation 630, the housing structure defined by the partition wall 310 may be filled with the hydrophobic oil 320. The hydrophobic oil 320 may have excellent barrier properties against oxygen and moisture to be suitable for the barrier and heat-sink. The hydrophobic oil 320 may have a refractive index of 1.29 to 1.6, a contact angle with water of 90 degrees or more, and a specific gravity of 1.2 or more.

In operation 640, a polymer thin film (for example, the polymer thin film 400 of FIG. 2) may be formed on the surface of the hydrophobic oil using a photo-curable precursor. The photo-curable precursor may be a mixture in which one or more of the reactive precursor, the photoinitiator, and the additive are combined. The polymer thin film 400 may have a thickness of 1 µm or less, and may be formed by coating the photo-curable precursor on the surfaces of the hydrophobic oil 320 and the partition wall 310 followed by the curing reaction, or by filling the housing structure with the liquid in which the photo-curable precursor is mixed with the hydrophobic oil 320 and curing the phase-separated photo-curable precursor.

In operation 650, a multi-film (for example, the multi-film 500 of FIG. 5) may be laminated on the polymer thin film 400. The multi-film 500 may be formed by laminating an adhesive sheet that is one of the double-sided adhesive and the double-sided adhesive film (for example, the adhesive sheet 510 in FIG. 5) and an encapsulation layer (for example, the encapsulation of FIG. 5) on the polymer thin film 400 to protect the organic light emitting device 200 from moisture, oxygen, and damage from the outside. In the multi-film 500, the moisture absorption layer 530 may be inserted between the adhesive sheet 510 and the encapsulation layer 520 or the moisture absorbent may be added to the double-sided adhesive to absorb moisture and oxygen in the atmosphere.

As described above, although the example embodiments have been described with reference to the limited drawings, those skilled in the art may apply various technical modifications and variations based thereon. For example, the described techniques may be performed in an order different from the described method, and/or the elements of the described system, structure, apparatus, circuit, etc. may be combined or organized in a different form from the described method or may be replaced or substituted by other elements or equivalents to achieve an appropriate result.

Therefore, other implementations, other example embodiments, and equivalents to the following claims also fall within the scope of the claims.

What is claimed is:

1. An encapsulated organic light emitting device comprising:
a plurality of organic light emitting devices formed on a substrate;
a partition wall disposed to separate the plurality of organic light emitting devices;
a hydrophobic oil filling a housing structure defined by the partition wall;
a polymer thin film formed on surfaces of the hydrophobic oil and the partition wall using a photo-curable precursor; and
a multi-film laminated on the polymer thin film.

2. The encapsulated organic light emitting device of claim 1, wherein the height of the partition wall is 0.5 µm to 5 µm, and
the partition wall is a trapezoidal pixel defining layer (PDL) with a lower portion wider than an upper portion.

3. The encapsulated organic light emitting device of claim 1, wherein the hydrophobic oil has a refractive index of 1.29 to 1.6, a contact angle with water of 90 degrees or more, and a specific gravity of 1.2 or more, and
the hydrophobic oil is one of fluorine oil, siloxane oil, paraffin oil, amorphous fluorine-based oil, silicone oil, mineral oil, almond oil, corn oil, cottonseed oil, linseed oil, tung oil, castor oil, cinnamin oil, and coconut oil, and
wherein the fluorine oil comprises an amorphous fluoropolymer,
the siloxane oil comprises polyphenyl-methyl siloxane, polydiphenyl siloxane, and polydimethyl siloxane, and
the amorphous fluorine-based oil comprises tetrafluoroethylene, trifluoroethylene, difluoroethylene, 2,2-bisfluoromethyl-4,5-difluoro-1,3-dixole, and chlorotrifluoroethyl ene.

4. The encapsulated organic light emitting device of claim 1, wherein the polymer thin film has a thickness of 1 µm or less, and
the polymer thin film is formed by coating the photo-curable precursor on the surfaces of the hydrophobic oil and the partition wall followed by a curing reaction, or by filling the housing structure with a liquid in which the photo-curable precursor is mixed with the hydrophobic oil followed by a curing reaction of a phase-separated photo-curable precursor.

5. The encapsulated organic light emitting device of claim 4, wherein the photo-curable precursor is a mixture in which one or more of a reactive precursor, a photoinitiator, and an additive are combined.

6. The encapsulated organic light emitting device of claim 5, wherein the reactive precursor has a specific gravity of 1.0 to 1.2 and has less miscibility and specific gravity than the hydrophobic oil, and
the reactive precursor comprises one or more of 1,6-hexandiol diacrylate (HAD), 2-hydroxyethyl methacrylate (2-HEMA), 2-ethylheeth acrylate, hydroxyethyl acrylate (HEA), methyl methacrylate (MMA), methacrylate (MA), isobornyl acrylate (IOBA), 2-(2-ethoxyethoxy) ethyl acrylate (EOEOEA), triethylopropane triacrylate (TMPTA), trimethylolpropane dially ether (TMPDE), tri(propylene glycol) diacrylate (TPGDA), pentaerythritol triacrylate (PETA), ethylene glycol dimethacrylate (EGDA), triethylopropane trimethacrylate (TMPTMA), 2-phenoxyethyl acrylate (2-PEA), trimethylolpropane ethoxylate triacrylate (TMPEOTA), tetrahydrofurfuryl acrylate (THFA), and urethane diacrylate.

7. The encapsulated organic light emitting device of claim 5, wherein the photoinitiator has a weight of 0.1% to 10% of the polymer thin film and is a mixture of two or more UV curing agents.

8. The encapsulated organic light emitting device of claim 4, wherein the curing reaction uses ultraviolet rays having a wavelength in a range of 300 nm to 400 nm, and uses photocuring energy of 20 mJ to 2000 mJ.

9. The encapsulated organic light emitting device of claim 1, wherein the multi-film is formed by laminating an encapsulation layer on an adhesive sheet comprising one of a double-sided adhesive made using a double-sided adhesive film and the double-sided adhesive film, and
the encapsulation layer is one of an encapsulation film which is a film in which plastic and inorganic material are laminated or a multilayer film formed by laminating only the inorganic material, and a glass substrate.

10. The encapsulated organic light emitting device of claim 9, wherein the double-sided adhesive film is coated with an adhesive layer comprising only one polymer of acrylate and epoxy-based polymers, and
the double-sided adhesive is formed by repeating a structure in which the adhesive layer, a support for supporting the adhesive layer, and the adhesive layer are laminated.

11. The encapsulated organic light emitting device of claim 9, wherein the encapsulated organic light emitting device further comprises a moisture absorption layer for absorbing moisture and oxygen in the atmosphere between the encapsulation layer and the adhesive sheet, or
a moisture absorbent is added to the double-sided adhesive.

12. A fabrication method of fabricating an encapsulated organic light emitting device, the fabrication method comprising:
forming a plurality of organic light emitting devices on a substrate;
forming a partition wall disposed to separate the plurality of organic light emitting devices;
filling a housing structure defined by the partition wall with a hydrophobic oil;
forming a polymer thin film on surfaces of the hydrophobic oil and the partition wall using a photo-curable precursor; and
laminating a multi-film on the polymer thin film.

13. The fabrication method of claim 12, wherein the height of the partition wall is 0.5 µm to 5 µm, and
the partition wall is a trapezoidal pixel defining layer (PDL) with a lower portion wider than an upper portion.

14. The fabrication method of claim 12, wherein the hydrophobic oil has a refractive index of 1.29 to 1.6, a contact angle with water of 90 degrees or more, and a specific gravity of 1.2 or more.

15. The fabrication method of claim 12, wherein the polymer thin film has a thickness of 1 µm or less, and
the polymer thin film is formed by coating the photo-curable precursor on the surfaces of the hydrophobic oil and the partition wall followed by a curing reaction, or by filling the housing structure with a liquid in which the photo-curable precursor is mixed with the hydrophobic oil followed by a curing reaction of a phase-separated photo-curable precursor.

16. The fabrication method of claim 15, wherein the photo-curable precursor is a mixture in which one or more of a reactive precursor, a photoinitiator, and an additive are combined,
the reactive precursor has a specific gravity of 1.0 to 1.2 and has less miscibility and specific gravity than the hydrophobic oil, and
the photoinitiator has a weight of 0.1% to 10% of the polymer thin film and is a mixture of two or more UV curing agents.

17. The fabrication method of claim 12, wherein the multi-film is formed by laminating one of a double-sided adhesive made using a double-sided adhesive film and the double-sided adhesive film on an encapsulation layer, and
the encapsulation layer is one of an encapsulation film and a glass substrate.

18. The fabrication method of claim 17, wherein the double-sided adhesive film is coated with an adhesive layer comprising only one polymer of acrylate and epoxy-based polymers, and
the double-sided adhesive is formed by repeating a structure in which the adhesive layer, a support for supporting the adhesive layer, and the adhesive layer are laminated.

19. The fabrication method of claim 17, wherein the encapsulated organic light emitting device further comprises a moisture absorption layer for absorbing moisture and oxygen in the atmosphere between the encapsulation layer and the adhesive sheet, or
a moisture absorbent is added to the double-sided adhesive.

20. A display comprising:
an encapsulated organic light emitting device; and
a thin film transistor (TFT) inserted between a substrate of the encapsulated organic light emitting device and an organic light emitting device,
wherein the encapsulated organic light emitting device comprises:
a plurality of organic light emitting devices formed on the substrate;
a partition wall disposed to separate the plurality of organic light emitting devices;
a hydrophobic oil filling a housing structure defined by the partition wall;
a polymer thin film formed on surfaces of the hydrophobic oil and the partition wall using a photo-curable precursor; and
a multi-film laminated on the polymer thin film.
